(19) United States
(12) Patent Application Publication
(10) Pub. No.: US 2025/0275465 A1
(43) Pub. Date: Aug. 28, 2025

(54) DOPED PEROVSKITE SEMICONDUCTORS WITH P-TYPE, N-TYPE AND I-TYPE CONDUCTIVITIES

(71) Applicant: ZHEJIANG UNIVERSITY, Hangzhou (CN)

(72) Inventors: Dawei DI, Hangzhou (CN); Wentao XIONG, Hangzhou (CN); Baodan ZHAO, Hangzhou (CN)

(21) Appl. No.: 18/943,773

(22) Filed: Nov. 11, 2024

Related U.S. Application Data
(63) Continuation of application No. PCT/CN2024/100643, filed on Jun. 21, 2024.

(30) Foreign Application Priority Data
Feb. 23, 2024 (CN) 202410202637.2

(51) Int. Cl. H10K 85/50; C09K 11/06; H10K 50/135; H10K 85/60

(52) U.S. Cl. CPC H10K 85/50; C09K 11/06; H10K 85/6572; H10K 50/135

(57) ABSTRACT

Disclosed is a series of doped perovskite semiconductors capable of realizing p-type, n-type and i-type electrical conductivities; and the doped perovskite semiconductors can be divided into p-type, n-type and intrinsic (i)-type according to the polarities of electrical conduction. Characteristics of these perovskite semiconductors are adjustable. The compositions of the doped perovskite materials are A′₂Aₙ₋₁BₙX₃ₙ₊₁: D or ABX₃: D, wherein A′ is an organic cation, A is a monovalent cation, B is a metal cation, X is a monovalent anion, and D is a dopant. An optoelectronic device based on a doped perovskite semiconductor does not require electron transport layers or hole transport layers, thus simplifying the device structure, and reducing the complexity and cost of device fabrication. Light-emitting diodes, solar cells and transistors based on doped perovskite semiconductors are capable of delivering excellent performance.

### CROSS-REFERENCE TO RELATED APPLICATIONS

The present disclosure is a continuation-application of International (PCT) Patent Application No. PCT/CN2024/100643, filed on Jun. 21, 2024, which claims priority of Chinese Patent Application No. 202410202637.2, filed on Feb. 23, 2024, the entire contents of which are hereby incorporated by reference in their entirety.

### TECHNICAL FIELD

The present invention relates to the technical field of semiconductor materials and devices, and particularly to doped perovskite semiconductors capable of realizing p-type, n-type and i-type electrical conductivities.

### BACKGROUND OF THE PRESENT INVENTION

The reliable control of the polarity and electrical conductivity of semiconductors is a key technology of the modern electronic industry, which leads to many revolutionary inventions such as diodes, transistors, solar cells, photodetectors, light-emitting diodes and semiconductor lasers. Taking a conventional semiconductor material—silicon as an example, the n-type (with electrons as the majority carriers) or p-type (with holes as the majority carriers) doping of silicon can be realized by introducing an electron acceptor (such as boron) or an electron donor (such as phosphorus) into a crystal lattice, so that the electrical conduction performance is regulated and controlled. Various electronic and optoelectronic devices are realized by utilizing the rectification characteristics of a p-n junction. Perovskite material is a novel ionic crystal semiconductor, which has a crystal structure comprising, but being not limited to, cubic, orthorhombic and the like, wherein different ions are present in the crystal lattice, with the advantages of continuously adjustable band gap, long carrier diffusion, solution-processing, strong light absorption, high luminous quantum efficiency, pure luminous spectrum, and the like. However, due to the complexity of the crystal structure, it is difficult to realize the controllable electrical doping of perovskites, which limits the further developments of the perovskite materials and their application in the semiconductor industry. Since perovskite solar cells were first reported in 2009, the efficiency of the perovskite solar cells has been rapidly improved, which now has exceeded 26%, but they still fall behind conventional inorganic silicon solar cell in device stability and power-conversion efficiency. Meanwhile, perovskites are also excellent luminescent materials capable of being processed and prepared by a solution-based method, which was first reported to be used as perovskite light-emitting diodes in 2014, marking the beginning of the research on perovskite light-emitting diodes, gaining extensive attention in the past decade. Recently, their external quantum efficiencies have exceeded 30%, which are comparable to those of inorganic and organic light-emitting diodes. The controllable electrical doping of perovskite semiconductors has not been realized, and it is difficult to precisely control the polarity of electrical conduction and the carrier concentrations for perovskite semiconductors, limiting the further development of perovskite semiconductors and their optoelectronic devices. The controllable doping of perovskite semiconductor materials has many benefits: 1. the electrical conduction types (polarity), the resistivity, the conductivity, the carrier concentration, the carrier mobility, the Fermi energy level, the energy band alignment, the optoelectronic characteristics and the like of the perovskite semiconductor materials may be precisely regulated and controlled; 2. a range of p-type, n-type and i-type perovskite semiconductor materials may be designed and developed, and homojunctions or heterojunctions with different functions are designed and prepared based on one or more types of perovskite semiconductor materials, which further expands the library of the fundamental building blocks of perovskite devices, and helps to realize a variety of novel devices with perovskite semiconductors, comprising, but being not limited to, diodes, transistors, solar cells, detectors, scintillators, light-emitting diodes, semiconductor lasers, and the like; 3. the doped perovskite semiconductors may allow the perovskite devices to function without charge-transport materials (for example, perovskite optoelectronic devices without hole- and/or electron-transport layers), thus greatly simplifying the fabrication of perovskite devices, reducing the cost and improving the reproducibility, as well as the production yields; and 4. the controllable doping of perovskite semiconductors can greatly enrich the library of perovskite materials, so that the perovskite semiconductor materials can achieve performance comparable to or exceed that of conventional semiconductors (such as silicon, III-V semiconductors, and the like). Therefore, the doped perovskite semiconductors realized by the present invention is very important for the emerging field of perovskite semiconductors and optoelectronic devices, and is expected to achieve unprecedented device performance and allow the creation of novel semiconductor devices.

### SUMMARY OF THE PRESENT INVENTION

Aiming at the limitations in the prior art, the present invention provides doped perovskite semiconductors capable of realizing p-type, n-type and i-type electrical conductivities.

As a new class of semiconductor material, perovskite semiconductors show complex structure and composition. The controllable electrical doping of the perovskite semiconductor was not realized in the past. It is difficult to precisely control the electronic conductivity type and electronic characteristics of the perovskite semiconductor, restricting the further development of perovskite semiconductors and their optoelectronic devices. Aiming at this important technical problem, the present invention realizes controllable doping of perovskite semiconductors and their optoelectronic device thereof. Doped perovskite semiconductors may be divided into p-type perovskites with holes as the majority carriers, n-type perovskites with electrons as the majority carriers and i-type perovskite with bipolar charge-transport properties. Compositions of doped perovskite materials are A′₂Aₙ₋₁BₙX₃ₙ₊₁: D (n=1, 2, 3, . . . ) or ABX₃:D, wherein A′ is an organic cation, A is a monovalent cation, B is a metal cation, X is a monovalent anion, and D is the dopant (by taking the metal cation B as a reference, a molar ratio of D to B is in the range of 0% to 80%). Dopants can be divided into p-type dopants and n-type dopants according to the effects of doping, wherein the p-type dopant can inhibit the formation of an electron-donating energy level in the perovskite semiconductors or show an electron-withdrawing effect, and can realize a perovskite semiconductor with an enhanced p-type character or a weakened n-type character; and the n-type dopant can inhibit the formation of an electron-accepting energy level in the perovskite semiconductors or show an electron-donating effect, and can realize a perovskite semiconductor with an enhanced n-type character or a weakened p-type character. A structure of the dopant is characterized in having a lone pair-containing functional group or a functional group capable of providing an unoccupied electron orbit or generating ions by ionization to partially replace the positions of some ions in a perovskite crystal lattice, so that the dopant may be subjected to coordination, covalent bonding, interionic interaction, hydrogen bonding, and the like with ions in the perovskite crystal structure, so as to achieve the above doping effects. The dopants may be categorized into organic polymer materials, organic small molecular materials, organic salts, inorganic salts, Lewis bases, Lewis acids, and the like according to their compositions. The preparation methods of the controllably doped perovskite semiconductor materials include, but are not limited to: 1. dissolving A′X (one or more), AX (one or more), BX (one or more) and the dopant in a solvent to obtain perovskite precursor solution, and preparing a doped perovskite material by a solution-process method; 2. dissolving A′X (one or more), AX (one or more) and BX (one or more) in solvent to obtain perovskite precursor solution and preparing perovskite materials, and introducing the dopant into the perovskite through processes of anti-solvent treatment, surface modification, solution fumigation, solid-state diffusion, ion implantation, and the like to obtain doped perovskite semiconductor materials; 3. preparing A′X (one or more), AX (one or more) and BX (one or more) to form perovskite semiconductor materials by a non-solution method such as magnetron sputtering, solid state reaction, vapor deposition and evaporation, and introducing the dopant into the perovskite through processes of anti-solvent treatment, surface modification, solution fumigation, solid state diffusion, ion implantation, and the like to obtain doped perovskite semiconductor materials; and 4. preparing the doped perovskite semiconductor material by the combination of two or more of the aforementioned processes. Homojunctions or heterojunctions with various functionalities may be formed by using one or more of different perovskite semiconductor materials prepared by the aforementioned dopants and methods, which enriches the library of the fundamental building blocks of perovskite electronic or optoelectronic devices, and the perovskite semiconductor materials may be used for preparing the perovskite electronic or optoelectronic devices, including, but being not limited to, diodes, transistors, solar cells, detectors, scintillators, light-emitting diodes, semiconductor lasers, and the like. The perovskite electronic or optoelectronic devices consist of doped perovskite materials and one or more of device functional materials such as a substrate, an anode, an electron transport material, a hole transport material and a cathode. The doped perovskite semiconductors can function in electronic devices without the aid of complicated electron-transport layers or hole transport layers, allowing the construction of perovskite electronic and optoelectronic devices without charge-transport layers. This kind of devices have a simpler preparation process, and can reduce the complexity and cost of device fabrication, and improve the reproducibility and manufacturing yield.

### The Technical Solution of the Present Invention is as Follows

The present invention discloses doped perovskite semiconductors, the corresponding doping methods, and electronic and optoelectronic devices thereof. A general structural formula of the perovskite semiconductor materials is D: A′₂Aₙ₋₁BₙX₃ₙ₊₁ (n=1,2,3, . . . ) or D: ABX₃, wherein A′ is an organic cation; A is a monovalent cation, such as a cesium ion (Cs⁺), a methylamine ion (MA⁺), a formamidine ion (FA⁺), an ethylamine ion (EA⁺), a hydrazine ion (HA⁺), a guanidine ion (GA⁺), an isopropylamine ion (IPA⁺) and an imidazole ion (IA⁺); B is a metal cation, such as a lead ion (Pb²⁺), a tin ion (Sn²⁺) and a germanium ion (Ge²⁺); and X is an anion, comprising a chloride ion (Cl⁻), a bromine ion (Br⁻), an iodine ion (I⁻), and the like; and D is a dopant.

A p-type perovskite semiconductor refers to a perovskite material in which the majority carriers responsible for electrical conduction are holes, and shows a p-type character; a n-type perovskite semiconductor refers to a perovskite material in which the majority carriers responsible for electrical conduction are electrons, and shows an n-type character; an i-type perovskite semiconductor refers to a perovskite material in which the concentration of electrons responsible for electrical conduction is comparable to that of holes, and shows an insulating behavior or bipolar charge transport characteristics; the perovskite semiconductor's band gap is adjustable, and the band gap is generally in the range of 0.5 eV to 4 eV; at room temperature, the carrier concentration is generally in the range of 10¹⁰ cm⁻³ to 10²⁰ cm⁻³; at room temperature, the carrier mobility is generally in the range of 10⁻⁴ cm²V⁻¹s⁻¹ to 1000 cm²V⁻¹s⁻¹; the photoluminescence quantum yield is generally in the range of 0.1% to 95%; and by introducing a dopant into the perovskite semiconductor, the above electronic or optoelectronic characteristics are reliably regulated and controlled.

The dopants can comprise, but are not limited to, organic polymer materials, organic small molecular materials, organic salts, inorganic salts, Lewis bases, Lewis acids, and the like. The dopant capable of inhibiting the formation of electron-donating energy levels or showing electron-withdrawing effects could make the perovskite material to exhibit an enhanced p-type character or weakened n-type character; the dopant capable of inhibiting the formation of electron-accepting energy levels or showing electron-donating effect could make the perovskite material to exhibit an enhanced n-type character or a weakened p-type character; and the use of one or more dopants at the same time neutralizes the formation of electron-donating energy levels and the formation of electron-accepting energy levels in the perovskite material, and neutralizes the electron-withdrawing effect and the electron-donating effect of the dopants, so that the dopants may be used to prepare an i-type (intrinsic) perovskite semiconductor, showing an insulating behavior or bipolar charge-transport characteristics. The preparation methods of the controllably doped perovskite semiconductor material may be one or a combination of the following preparation methods. The preparation methods include: dissolving A′X (one or more), AX (one or more), BX (one or more) and the dopant in solvent to obtain perovskite precursor solution, and preparing doped perovskite materials by a solution-processing method; dissolving A′X (one or more), AX (one or more) and BX (one or more) in solvent to obtain perovskite precursor solution and preparing perovskite materials, and then introducing the dopant into the perovskite through processes of anti-solvent treatment, surface modification, solution fumigation, solid-state diffusion, ion implantation, and the like to obtain doped perovskite semiconductor materials; preparing A′X (one or more), AX (one or more) and BX (one or more) to form perovskite semiconductor materials by a non-solution method such as magnetron sputtering, solid state reaction, vapor deposition and evaporation, and introducing the dopant into the perovskite through processes of anti-solvent treatment, surface modification, solution fumigation, solid state diffusion, ion implantation, and the like to obtain doped perovskite semiconductor materials. Physical forms of the perovskite semiconductor obtained by the preparation and doping methods may comprise, but be not limited to, a polycrystalline thin film, a single crystal, a nanocrystal, a quantum dot, a nanowire and a nanosheet, and a mixed material of the perovskite material above with one and more of an organic small molecule, a polymer, a metal oxide, a III-V semiconductor, a II-VI semiconductor, a metal, an inorganic dielectric, a nanomaterial, and the like. In the preparation and doping methods, the dopants comprise, but are not limited to, the following listed compounds, and may be any one or a mixture in any proportion of the following compounds: (2-(9H-carbazole-9-yl)ethyl)phosphonic acid (2PACz), 2-(3,6-dimethoxy-9H-carbazole-9-yl)ethyl]phosphonic acid (MeO-2PACz), [2-(3,6-dimethyl-9H-carbazole-9-yl)ethyl]phosphoric acid (ME-2PACz), [2-(3,6-dibromo-9H-carbazole-9-yl)ethyl]phosphonic acid (Br-2PACz), [4-(9H-carbazole-9-yl)butyl]phosphonic acid (4PACz), [4-(3,6-dibromo-9H-carbazole-9-yl)butyl]phosphonic acid (Br-4PACz), [4-(3,6-dimethoxy-9H-carbazole-9-yl)butyl]phosphonic acid (MeO-4PACz), [4-(3,6-dimethyl-9H-carbazole-9-yl)butyl]phosphoric acid (ME-4PACz), 3-(carbazole-9-yl)propionic acid, potassium bromide, sodium bromide, rubidium bromide, europium bromide, and the like. A lone pair-containing functional group common in molecules of the organic dopant and a functional group common in the Lewis base comprise, but are not limited to, a phosphate group (—PO(OH)₂), a phosphoryl chloride group (—P(O)Cl₂), a phosphoryl group (—P(O)R₂), an organic phosphate group (—OP(O)(OR)₂), a sulfonic acid group (—SO₃H), a thioketone group (—S(═O)—R), an amino group (—NH₂), a hydroxyl group (—OH), a cyano group (—CN), an aldehyde group (—CHO), a carboxyl group (—COOH), a ketone group (—C═O—R), a nitrile group (—N≡C), and the like. An unoccupied electron orbit-containing functional group common in molecules of the organic dopant and a functional group common in the Lewis acid comprise, but are not limited to, a carbon-carbon double bond group (—C═C), a carbon-carbon triple bond group (—C≡C), a boric acid (BF₃), and the like. An ion common in molecules of the inorganic dopant comprises, but is not limited to, a sodium ion (Na⁺), a potassium ion (K⁺), a rubidium ion (Rb⁺), a europium ion (Eu²⁺), a strontium ion (Sr²⁺), a silver ion (Ag⁺), an indium ion (In²⁺), a bismuth ion (Bi²⁺), and the like.

The electronic or optoelectronic device based on the controllably doped perovskite semiconductor materials generally consists of the doped perovskite material and one or more of device functional layers or materials such as a substrate, an anode, an electron-transport material, a hole-transport material and a cathode, which can be used to form diodes, transistors, solar cells, detectors, scintillators, light-emitting diodes, semiconductor lasers, and the like. Homojunctions or heterojunctions with different functions composed of one or more doped perovskite semiconductor materials are also important fundamental building blocks for the aforementioned electronic or optoelectronic device. The realization of the controllably doped perovskite semiconductor materials greatly enriches the library of such device building blocks. The doped perovskite semiconductors are able to function without the need for electron-transport or hole-transport materials, realizing perovskite optoelectronic devices without charge-transport layers. This type of devices have a simpler preparation process, and can reduce the complexity and cost of device preparation, and improve the reproducibility and production yield. For light-emitting diodes based on doped perovskite semiconductor materials, the maximum external quantum efficiency (EQE) is generally in the range of 10% to 30%, and the maximum external quantum efficiency can reach above 30% after optimization; an electroluminescent peak wavelength is generally in the range of 300 nm to 2000 nm; the maximum radiance is greater than 20 W sr⁻¹ m⁻² (in the case of visible perovskite light-emitting diodes, the maximum luminance is greater than 10000 cd m⁻²), and the maximum radiance is greater than 2000 W sr⁻¹ m⁻² after optimization (in the case of visible perovskite light-emitting diodes, the maximum luminance is greater than 1000000 cd m⁻² after optimization). For solar cells based on doped perovskite semiconductor materials, under the conditions of single-junction solar cell configuration and 1-sun standard illumination, the power conversion efficiency (PCE) is generally in the range of 10% to 30%, and the power conversion efficiency can reach above 30% after optimization; and the fill factor (FF) is generally in the range of 60% to 85%, and the fill factor can reach above 85% after optimization. For a multi-junction tandem solar cell and other configurations, the power conversion efficiency can reach above 35%. For transistors based on doped perovskite semiconductors, at room temperature, the carrier mobility is greater than 10⁻⁴ cm²V⁻¹s⁻¹, and the mobility can reach 100 cm²V⁻¹s⁻¹ or above after optimization.

When the hole concentration in the p-type perovskite semiconductor reaches above 10¹⁸ cm⁻³, the p-type perovskite semiconductor is also called a “heavily doped p-type perovskite semiconductor” or a “p⁺-type perovskite semiconductor”; and when the electron concentration in the n-type perovskite semiconductor reaches above 10¹⁸ cm⁻³, the n-type perovskite semiconductor is also called a “heavily doped n-type perovskite semiconductor” or an “n⁺-type perovskite semiconductor”.

### The Present Invention Has the Following Beneficial Effects

(1) The present invention realizes p-type, n-type and i-type perovskite semiconductors, and realizes the precise regulation and control of the polarity of charge conduction, the electrical resistivity, the electrical conductivity, the carrier concentrations, the carrier mobility, the Fermi levels, the energy band alignment, the optoelectronic characteristics, and the like of the perovskite semiconductors.

(2) The present invention may be used for constructing perovskite electronic or optoelectronic devices, which can be, but are not limited to, diodes, transistors, solar cells, detectors, scintillators, light-emitting diodes, semiconductor lasers, and the like.

(3) According to the present invention, one or more types of p-type, n-type or i-type perovskite semiconductor materials are used to form a homojunction or a heterojunction, which expands the library of basic constructing units of perovskite devices, thus realizing a variety of novel semiconductor devices.

(4) According to the present invention, the doped perovskite semiconductors can allow perovskite devices to function without the need for electron-transport and/or hole transport materials, and can realize perovskite electronic and optoelectronic devices without charge-transport layers. This type of devices have a simpler preparation process, which can reduce the complexity and cost of device fabrication, and improve the reproducibility and the manufacturing yield.

(5) The doped perovskite semiconductors and technology of the present invention can realize the precise regulation and control of electronic and optoelectronic performances of perovskite semiconductors, so that the perovskite electronic and optoelectronic devices with performance close to or exceeding those of conventional semiconductor devices (such as silicon and III-V semiconductors) may be obtained.

### DESCRIPTION OF THE DRAWINGS

FIG. 1 is a schematic diagram of a crystal structure of an undoped perovskite material in Embodiment 1 of the present invention;

FIG. 2 is a schematic diagram of a crystal structure of a doped perovskite material in Embodiment 1 of the present invention;

FIG. 3 is a current density-voltage characteristic relationship diagram of the perovskite light-emitting diode in Embodiment 1 of the present invention;

FIG. 4 is a radiance-voltage characteristic relationship diagram of a perovskite light-emitting diode in Embodiment 1 of the present invention;

FIG. 5 is a microscope image of a surface of a thin film of undoped perovskite in Embodiment 1 of the present invention in a Darwin probe;

FIG. 6 is a image of the undoped perovskite film with 1% doping ratio (dopant relative to Pb²⁺) from kelvin probe force microscopy measurement in Embodiment 1 of the present invention;

FIG. 7 is a image of the undoped perovskite film with 3% doping ratio (dopant relative to Pb²⁺) from kelvin probe force microscopy measurement in Embodiment 1 of the present invention;

FIG. 8 is a image of the undoped perovskite film with 5% doping ratio (dopant relative to Pb²⁺) from kelvin probe force microscopy measurementin Embodiment 1 of the present invention;

FIG. 9 is a schematic diagram of a contact potential difference of surfaces of perovskite films with different doping concentrations in Embodiment 1 of the present invention;

FIG. 10 shows Hall coefficient test results of perovskite materials with different doping concentrations in Embodiment 1 of the present invention;

FIG. 11 shows majority carrier types and concentration test results of the perovskite materials with different doping concentrations in Embodiment 1 of the present invention;

FIG. 12 shows a theoretical calculation model of undoped perovskite materials in Embodiment 2 of the present invention;

FIG. 13 shows a theoretical calculation model of doped perovskite materials in Embodiment 2 of the present invention;

FIG. 14 shows formation energy calculation results of different deficiencies in the undoped perovskite in Embodiment 2 of the present invention;

FIG. 15 is the electron cloud intensity distribution diagram of the undoped perovskite in Embodiment 2 of the present invention;

FIG. 16 is the electron cloud intensity distribution diagram of the doped perovskite in Embodiment 2 of the present invention;

FIG. 17 is a diagram of densities of states/(E−E_{V}) in the undoped and doped perovskite materials in Embodiment 2 of the present invention;

FIG. 18a and FIG. 18b are schematic diagrams of the doping mechanism of perovskite based on density functional calculation results in Embodiment 2 of the present invention;

FIG. 19 is a nuclear magnetic resonance spectrum of 4PACz with or without PbBr₂ in Embodiment 2 of the present invention;

FIG. 20 is a Fourier transform infrared absorption spectrogram of the 4PACz and the doped perovskite material in Embodiment 2 of the present invention;

FIG. 21 shows an X-ray photoelectron spectroscopy of the undoped and doped perovskite materials in Embodiment 2 of the present invention;

FIG. 22 is a structural diagram of a perovskite light-emitting diode device without a hole transport layer in Embodiment 3 of the present invention;

FIG. 23 is a cross-sectional transmission electron microscope image of the perovskite light-emitting diode without the hole transport layer in Embodiment 3 of the present invention;

FIG. 24a to FIG. 24d are performance comparison diagrams of light-emitting diodes without the hole transport layer based on perovskite at different doping concentrations in Embodiment 3 of the present invention;

FIG. 25 is a luminescence spectrogram of light-emitting diodes without the hole transport layer based on undoped perovskite and perovskite at 5% doping concentration in Embodiment 3 of the present invention;

FIG. 26 shows a current density-voltage curve of the light-emitting diodes without the hole transport layer based on undoped perovskite and perovskite at 5% doping concentration in Embodiment 3 of the present invention;

FIG. 27 shows a luminance-voltage curve of the light-emitting diodes without the hole transport layer based on undoped perovskite and perovskite at 5% doping concentration in Embodiment 3 of the present invention;

FIG. 28 shows an external quantum efficiency-luminance curve of the light-emitting diodes without the hole transport layer based on undoped perovskite and perovskite at 5% doping concentration in Embodiment 3 of the present invention;

FIG. 29 shows an energy conversion efficiency-luminance curve of the light-emitting diodes without the hole transport layer based on undoped perovskite and perovskite at 5% doping concentration in Embodiment 3 of the present invention;

FIG. 30 is a photoluminescence efficiency statistical diagram of thin films of perovskite at different doping concentrations in Embodiment 3 of the present invention; and

FIG. 31 is a transient photoluminescence spectrogram of thin films of undoped perovskite and perovskite at 5% doping concentration in Embodiment 3 of the present invention.

### DETAILED DESCRIPTION OF PREFERRED EMBODIMENTS

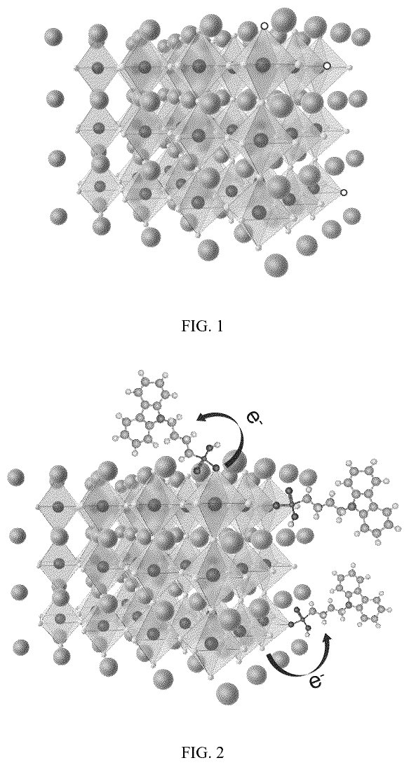

FIG. 1 is a schematic diagram of a crystal structure of an undoped perovskite material; and FIG. 2 is a schematic diagram of a crystal structure of a doped perovskite material. An unsaturated B-site in perovskite may interact with an acidic group in a dopant. The dopant provides an electron-donating group or an electron-withdrawing group for a perovskite material, inhibits an amount of unsaturated lead in perovskite to inhibit the formation of an electron-donating or electron-accepting energy level caused by related deficiencies, regulates and control types (electrons or holes) and a number of majority carriers in related perovskite materials, and regulates and controls electrical conduction types of related perovskite materials. The perovskite material subjected to fine doping regulation and control may have appropriate carrier mobility and carrier density, so as to realize the successful preparation of an efficient and bright light-emitting diode without a hole transport layer or an electron transport layer.

### (1) Preparation of Perovskite Precursor Solution

The perovskite precursor solution is prepared by dissolving A′X, AX, BX₂ and a dopant P in a solvent (which may be any one or a mixed solvent of DMF, DMSO, GBL, NMP, acetonitrile, G-butyrolactone, and the like), wherein A′ is an organic amine cation, A is a monovalent cation, such as a cesium ion (Cs⁺), a methylamine ion (MA⁺), a methylamine ion (FA⁺), an ethylamine ion (EA⁺), a hydrazine ion (HA⁺), a guanidine ion (GA⁺), an isopropylamine ion (IPA⁺) and an imidazole ion (IA⁺); B is a divalent metal cation, such as a lead ion (Pb²⁺), a tin ion (Sn²⁺) and a germanium ion (Ge²⁺); and X is an anion comprising a chloride ion (Cl⁻), a bromide ion (Br⁻), an iodide ion (I⁻), and the like. A concentration of the perovskite precursor solution is 0.01 mol/L to 2 mol/L.

### (2) Preparation of Perovskite Light-Emitting Diode

A substrate is soaked with water, deionized water, acetone and isopropyl alcohol (ITO) in sequence, and washed in an ultrasonic machine for more than 15 minutes. Before spin coating, the ITO glass substrate is processed by a plasma machine for 15 minutes. Subsequently, a thin film of perovskite is directly prepared on the ITO by a solution method, and annealed for a certain period of time, and an anti-solvent, such as any one or a mixed solvent of several of chlorobenzene, toluene, ethyl acetate, anhydrous ether, chloroform, and the like, is introduced in the process of spin coating. Subsequently, the electron or hole transport layer is prepared by spin coating, evaporation, magnetron sputtering, atomic layer deposition, and other methods. Finally, an electrode layer is prepared by evaporation, magnetron sputtering, atomic layer deposition, and other methods.

### 1. Embodiment 1 Controllable Doping of Perovskite Material

A perovskite precursor solution was prepared by dissolving FABr, MABr, GABr, CsBr, PbBr₂ and a dopant 4PACz in 1 ml of DMSO according to a molar ratio of 0.8:0.1:0.1:0.15:1:x (x=0-0.8) to obtain a solution at a concentration of 0.95 mol L⁻¹. A two-step spin coating method was used to prepare a thin film of perovskite on a substrate, and the substrate comprised, but was not limited to, an ITO substrate, a quartz glass substrate, a sapphire substrate, a silicon wafer, and the like, wherein the spin coating in the first step was carried out at a rotating speed of 500 r for 10 seconds, and the spin coating in the second step was carried out at a rotating speed of 5000 r for 90 seconds. About 40 seconds after the process of spin coating was started in the second step, 100 μL of anti-solvent was dropwise added onto a sample, the anti-solvent was a chloroform solvent with 2 mg/ml TPBI, and after the spin coating was ended, the thin film of perovskite was obtained by annealing at 90° C. for 10 minutes.

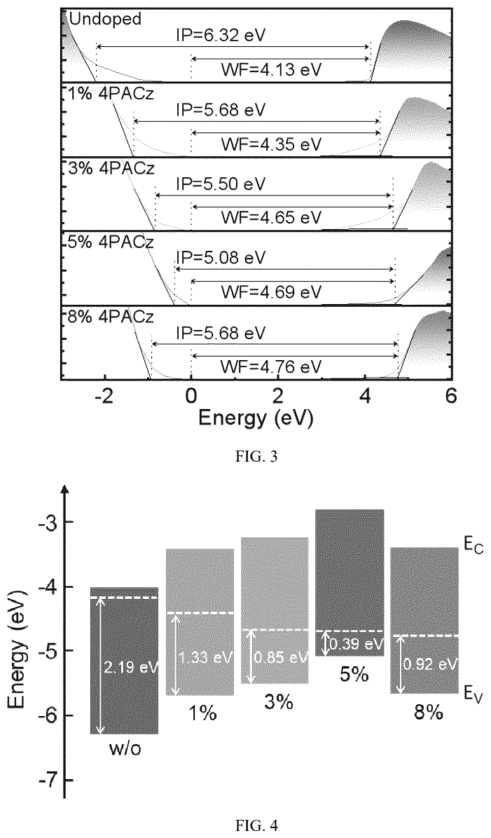

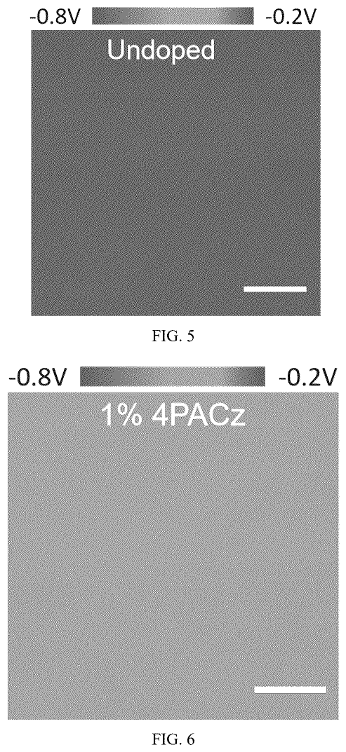

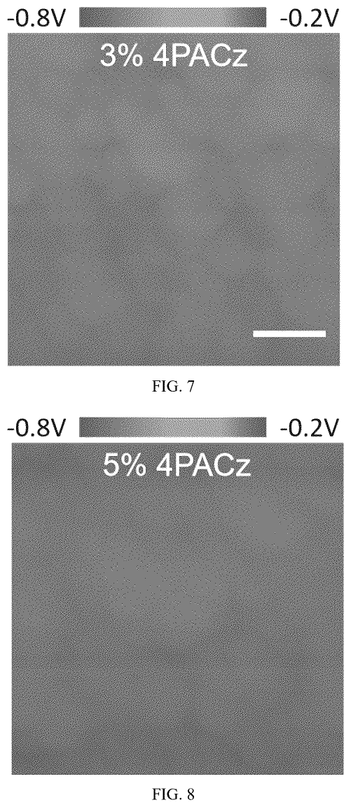

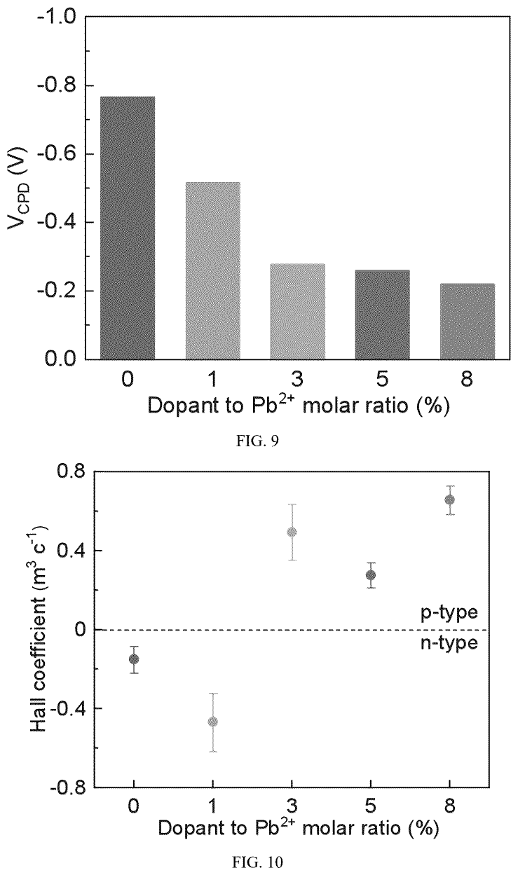

FIG. 3 shows test results of ultraviolet photoelectron spectroscopy of perovskite materials at different doping concentrations, wherein IP represents an ionization potential, and WF represents a work function. FIG. 4 shows an energy level arrangement diagram of perovskite materials at different doping concentrations, wherein Ev represents a bottom of valence band, and Ec represents a top of conduction band. FIG. 5 is a microscope image of a surface of a thin film of undoped perovskite in a Darwin probe, wherein a scale is 400 nm. FIG. 6 is a microscope image of a surface of a thin film of perovskite at 1% doping concentration (dopant relative to Pb²⁺) in a Darwin probe, wherein a scale is 400 nm. FIG. 7 is a microscope image of a surface of a thin film of perovskite at 3% doping concentration (dopant relative to Pb²⁺) in a Darwin probe, wherein a scale is 400 nm. FIG. 8 is a microscope image of a surface of a thin film of perovskite at 5% doping concentration (dopant relative to Pb²⁺) in a Darwin probe, wherein a scale is 400 nm. FIG. 9 is a schematic diagram of a contact potential difference of surfaces of thin films of perovskite at different doping concentrations. FIG. 10 shows Hall coefficient test results of perovskite materials at different doping concentrations. FIG. 11 shows majority carrier types and density test results of perovskite materials at different doping concentrations.

### 2. Embodiment 2 Construction of Perovskite Material Doping Model and Study on Mechanism Thereof

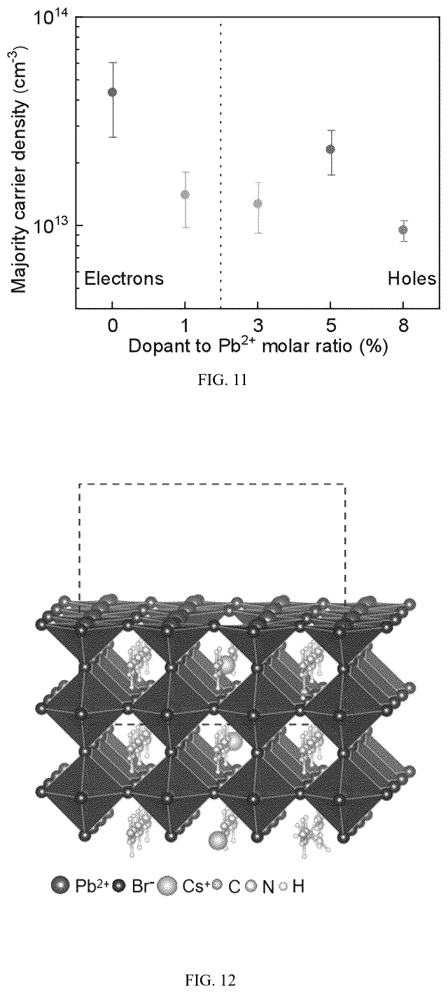

First-principle calculation based on a density functional theory was used to study a doping mechanism of perovskite. A related model was successfully constructed, and a series of calculations were made on this basis. FIG. 12 shows a theoretical calculation model of an undoped perovskite material.

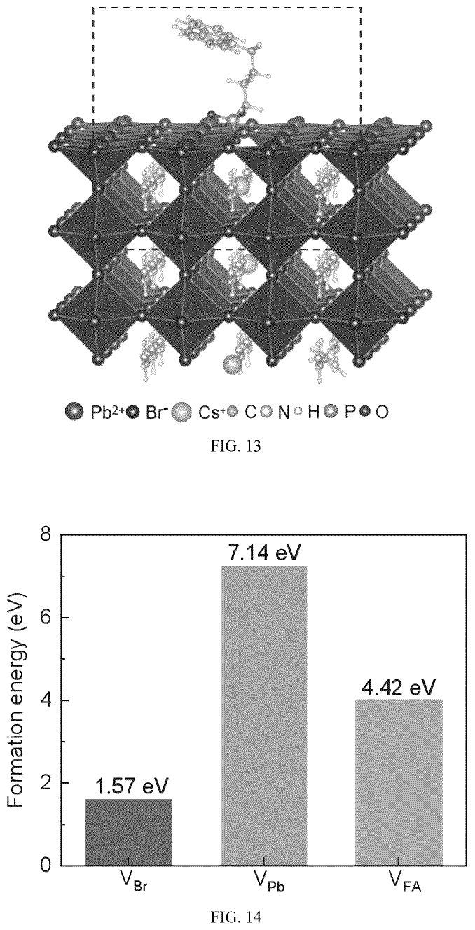

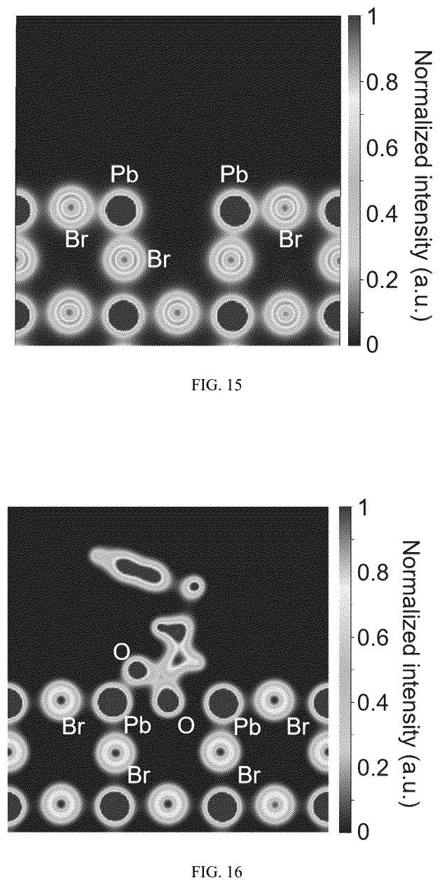

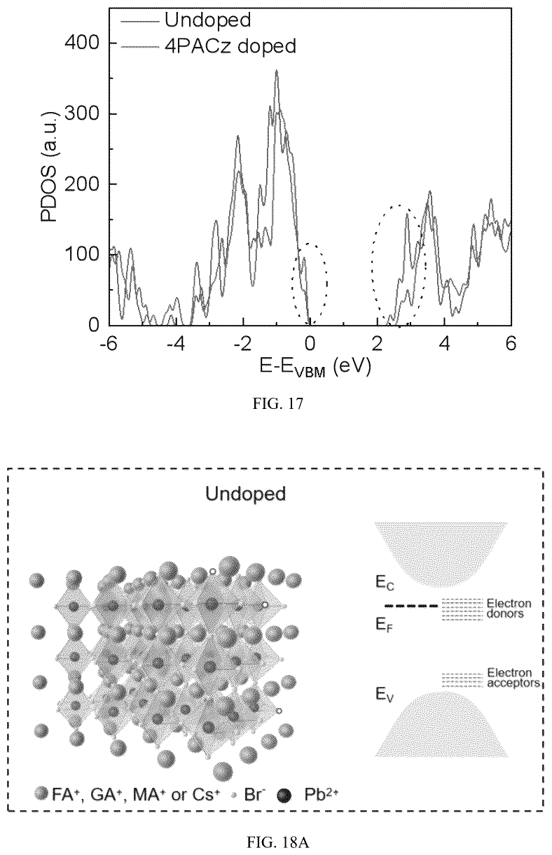

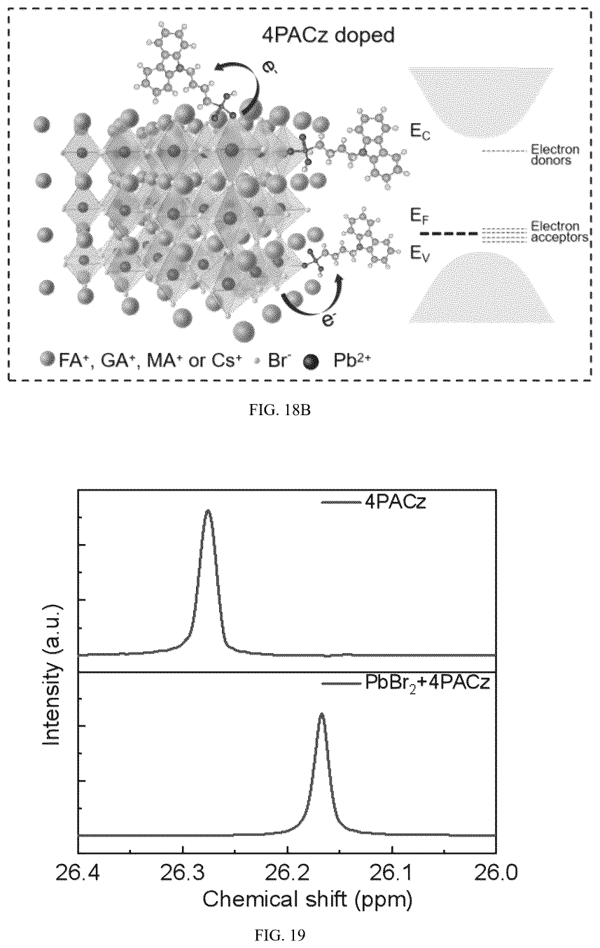

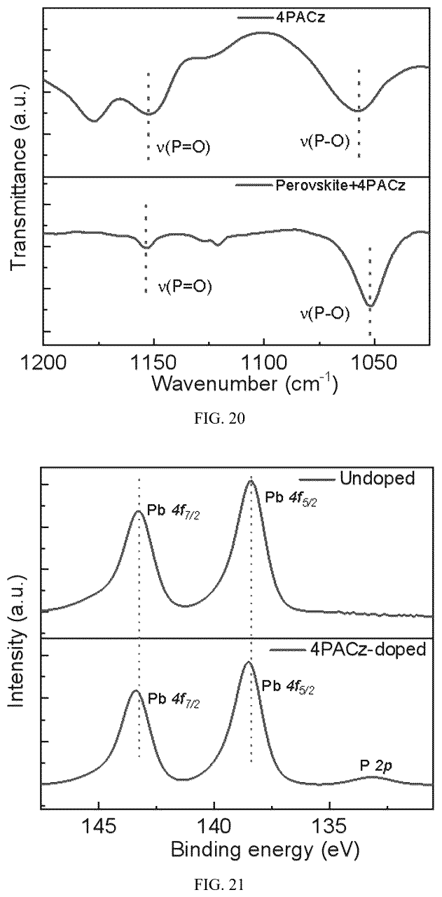

FIG. 13 shows a theoretical calculation model of a doped perovskite material. FIG. 14 shows formation energy calculation results of different deficiencies in the undoped perovskite. FIG. 15 is an electron cloud intensity distribution diagram of the undoped perovskite. FIG. 16 is an electron cloud intensity distribution diagram of the doped perovskite. FIG. 17 is a diagram of densities of states/(E−E_{V}) in the undoped and doped perovskite materials. FIG. 18 is a schematic diagram of a doping mechanism of perovskite based on density functional calculation results. FIG. 19 is a nuclear magnetic resonance spectrum of 4PACz with or without PbBr₂. FIG. 20 is a Fourier transform infrared absorption spectrogram of the 4PACz and the doped perovskite material. FIG. 21 shows an X-ray photoelectron spectroscopy of the undoped and doped perovskite materials.

### 3. Embodiment 3 Preparation of Perovskite Light-Emitting Diode Without Hole Transport Layer

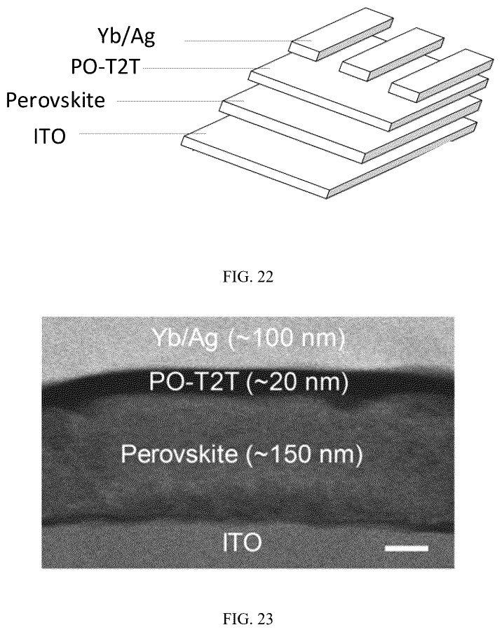

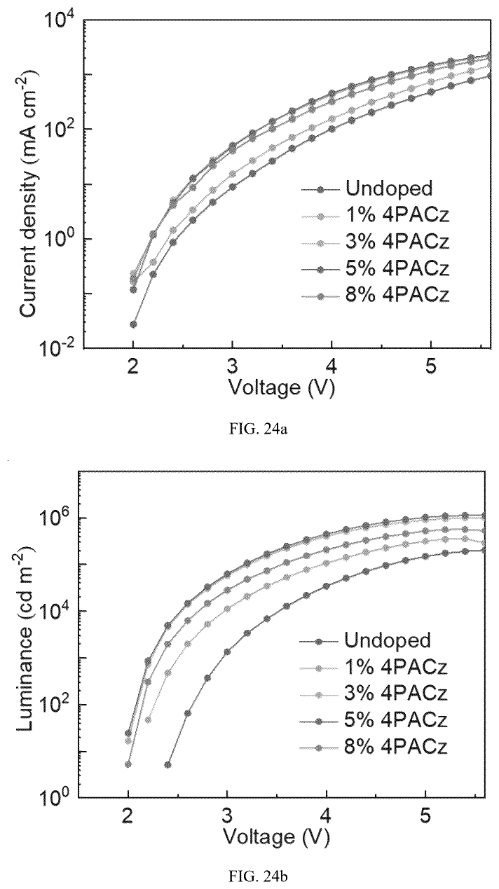

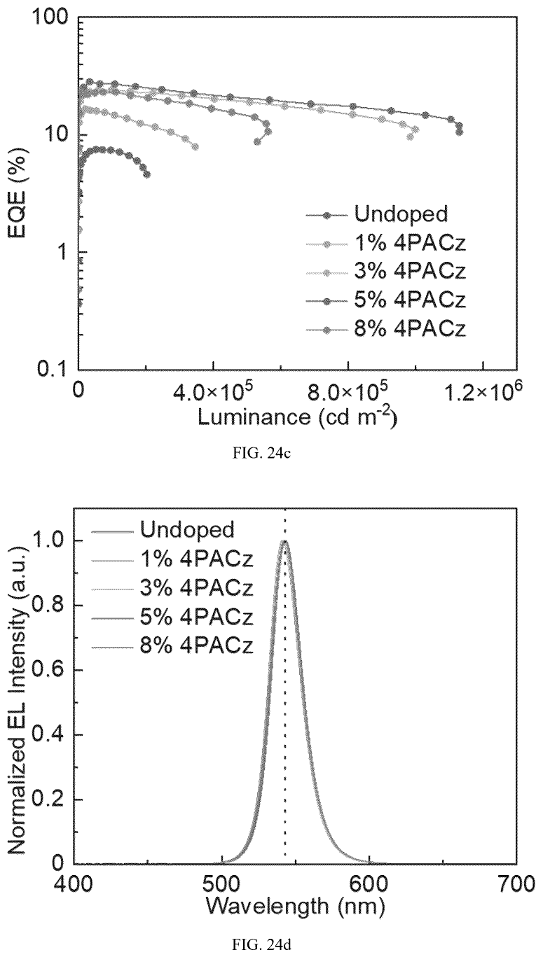

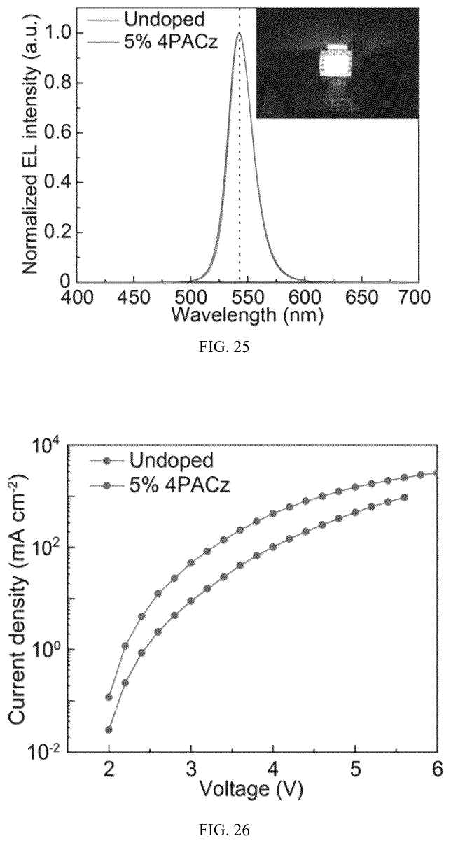

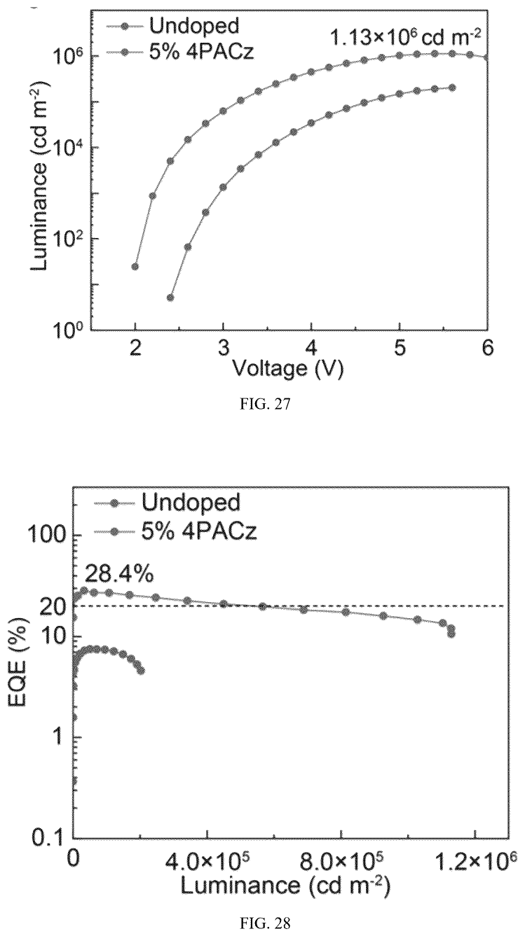

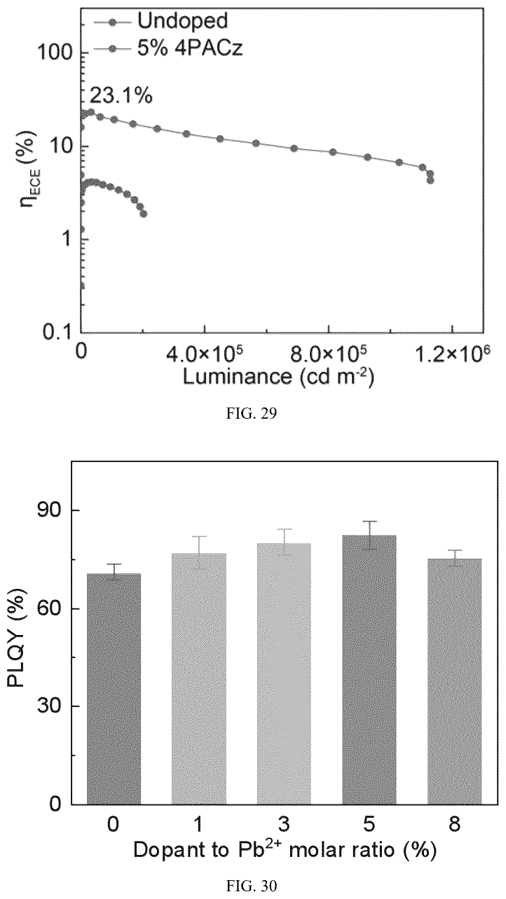

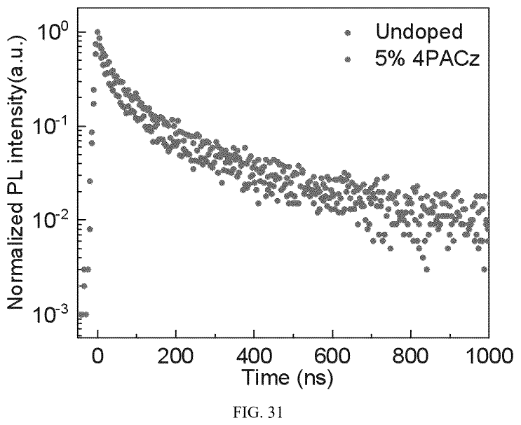

A substrate was soaked with water, deionized water, acetone and isopropyl alcohol in sequence, and washed in an ultrasonic machine for more than 15 minutes. Before spin coating, the substrate was processed by a plasma machine for 15 minutes. A perovskite precursor solution was prepared by dissolving FABr, MABr, GABr, CsBr, PbBr₂ and a dopant 4PACz in 1 ml of DMSO according to a molar ratio of 0.8:0.1:0.1:0.15:1:x (x=0-0.8) to obtain a solution at a concentration of 0.95 mol L⁻¹. A two-step spin coating method was used to prepare a thin film of perovskite on a substrate, and the substrate comprised, but was not limited to, an ITO substrate, a quartz glass substrate, a sapphire substrate, a silicon wafer, and the like, wherein the spin coating in the first step was carried out at a rotating speed of 500 r for 10 seconds, and the spin coating in the second step was carried out at a rotating speed of 5000 r for 90 seconds. About 40 seconds after the process of spin coating was started in the second step, 100 μL of anti-solvent was dropwise added onto a sample, the anti-solvent was a chloroform solvent with 2 mg/ml TPBI, and after the spin coating was ended, the thin film of perovskite was obtained by annealing at 90° C. for 10 minutes. An electron transport layer was made of PO-T2T, and an electrode was made of Yb/Ag. FIG. 22 is a structural diagram of a perovskite light-emitting diode device without a hole transport layer. FIG. 23 is a cross-sectional transmission electron microscope image of the perovskite light-emitting diode without the hole transport layer. FIG. 24 is a performance comparison diagram of light-emitting diodes without the hole transport layer based on perovskite at different doping concentrations. FIG. 25 is a luminescence spectrogram of light-emitting diodes without the hole transport layer based on undoped perovskite and perovskite at 5% doping concentration. FIG. 26 shows a current density-voltage curve of the light-emitting diodes without the hole transport layer based on undoped perovskite and perovskite at 5% doping concentration. FIG. 27 shows a luminance-voltage curve of the light-emitting diodes without the hole transport layer based on undoped perovskite and perovskite at 5% doping concentration. FIG. 28 shows an external quantum efficiency-luminance curve of the light-emitting diodes without the hole transport layer based on undoped perovskite and perovskite at 5% doping concentration. FIG. 29 shows an energy conversion efficiency-luminance curve of the light-emitting diodes without the hole transport layer based on undoped perovskite and perovskite at 5% doping concentration. FIG. 30 is a photoluminescence efficiency statistical diagram of thin films of perovskite at different doping concentrations. FIG. 31 is a transient photoluminescence spectrogram of thin films of undoped perovskite and perovskite at 5% doping concentration.

We claim:

1. Doped perovskite semiconductors capable of realizing p-type, n-type and i-type electrical conductivities, wherein compositions of doped perovskite materials are A′₂Aₙ₋₁BₙX₃ₙ₊₁: D or ABX₃, wherein n=1, 2, 3, . . . , A′ is an organic cation, A is a monovalent cation, B is a metal cation, X is a monovalent anion, and D is a dopant, and by taking the metal cation B as a reference, a molar ratio of D to B is in a range of 0% of 80%; a p-type perovskite semiconductor refers to a perovskite material in which the majority carriers responsible for electrical conduction are holes, and shows a p-type character; an n-type perovskite semiconductor refers to a perovskite material in which the majority carriers responsible for the electrical conduction are electrons, and shows an n-type character; an i-type perovskite semiconductor refers to a perovskite material in which the concentration of electrons responsible for electronic conduction is comparable to that of holes, and shows insulating behavior or a bipolar transport character; the band gap of perovskite semiconductors is adjustable, and the band gap is generally in the range of 0.5 eV to 4 eV; at room temperature, the carrier concentration is generally in the range of 10¹⁰ cm⁻³ to 10²⁰ cm⁻³; at room temperature, the carrier mobility is in generally the range of 10⁻⁴ cm² V⁻¹s⁻¹ to 1000 cm² V⁻¹s⁻¹; the photoluminescence quantum yield is generally in the range of 0.1% to 95%; and by introducing a dopant into the perovskite semiconductor, the above electrical or optoelectronic characteristics are reliably regulated and controlled.

2. The doped perovskite semiconductors capable of realizing p-type, n-type and i-type electronic conductivities according to claim 1, wherein a dopant capable of making the perovskite semiconductor p-type, enhancing the p-type character or weakening the n-type character after doping is a p-type dopant for the perovskite; a dopant capable of making the perovskite semiconductor n-type, enhancing the n-type character or weakening the p-type character after doping is an n-type dopant for the perovskite; wherein, a p-type dopant shows electron withdrawing ability when being introduced into the perovskite material is an electron acceptor, and provides extra holes for the perovskite semiconductor, so that the Fermi level moves toward the valence band; an n-type dopant shows electron donating ability when being introduced into the perovskite material is an electron donor, and provides extra electrons for the perovskite semiconductor, so that the Fermi level moves toward the conduction band; by introducing an n-type dopant into a p-type perovskite, an i-type or n-type perovskite semiconductor can be realized; by introducing a p-type dopant into an n-type perovskite, an i-type or p-type perovskite semiconductor can be realized; when the perovskite semiconductor is doped, one or more dopants with the same or opposite doping types are used, and the dosage is precisely regulated and controlled, so as to precisely regulate and control the polarity of electrical conduction, the resistivity, the electrical conductivity, the carrier concentration, the carrier mobility, the Fermi level, the energy band alignment and the optoelectronic characteristics of perovskite semiconductors.

3. The doped perovskite semiconductors capable of realizing p-type, n-type and i-type electrical conductivities according to claim 1, wherein A′ is an organic cation; A is a monovalent cation, such as a cesium ion, a methylamine ion, a formamidine ion, an ethylamine ion, a hydrazine ion, a guanidine ion, an isopropylamine ion or an imidazole ion; B is a metal cation, such as a lead ion, a tin ion or a germanium ion; X is an anion, such as a chloride ion, a bromine ion or an iodine ion; the dopant (D) can be, but are not limited to, organic polymer materials, organic small-molecule materials, organic salts, inorganic salts, Lewis bases, Lewis acids, or a combination of two or more of these materials.

4. The doped perovskite semiconductors capable of realizing p-type, n-type and i-type electrical conductivities according to claim 1, wherein a method of doping the perovskite semiconductor comprises: dissolving one or more types of A′X, one or more types of AX, one or more types of BX and one or more types of dopants in solvent to obtain a perovskite precursor solution, and preparing a doped perovskite semiconductor by a solution-process method; dissolving one or more types of of A′X, one or more types of AX and one or more types of BX in solvent to obtain a perovskite precursor solution and then forming the perovskite materials, and introducing the dopant into the perovskite through a process such as anti-solvent treatment, surface modification, solution fumigation, solid-state diffusion, ion implantation or a combination of any of these processes to obtain doped perovskite semiconductor materials; and preparing one or more of A′X, one or more types of AX and one or more types of BX to form perovskite semiconductor materials by a non-solution processing method, and introducing the dopant into the perovskite through a process such as anti-solvent treatment, surface modification, solution fumigation, solid state diffusion, ion implantation or a combination of any of these processes to obtain doped perovskite semiconductor materials.

5. The doped perovskite semiconductors capable of realizing p-type, n-type and i-type electrical conductivities according to claim 1, wherein the physical forms of the perovskite semiconductor can be polycrystalline thin films, single crystals, nanocrystals, quantum dot materials, nanowires and nanosheets, or a combination or mixture of any of the above physical forms with organic small molecules, polymers, metal oxides, III-V semiconductors, II-VI semiconductors, metals, inorganic dielectrics and nano-materials, or a combination of any of these materials.

6. The doped perovskite semiconductors capable of realizing p-type, n-type and i-type electrical conductivities according to claim 1, wherein the dopant comprises (2-(9H-carbazole-9-yl)ethyl)phosphonic acid, 2-(3,6-dimethoxy-9H-carbazole-9-yl)ethyl]phosphonic acid, [2-(3,6-dimethyl-9H-carbazole-9-yl)ethyl]phosphoric acid, [2-(3,6-dibromo-9H-carbazole-9-yl)ethyl]phosphonic acid, [4-(9H-carbazole-9-yl)butyl]phosphonic acid, [4-(3,6-dibromo-9H-carbazole-9-yl)butyl]phosphonic acid, [4-(3,6-dimethoxy-9H-carbazole-9-yl)butyl]phosphonic acid, [4-(3,6-dimethyl-9H-carbazole-9-yl)butyl]phosphoric acid, 3-(carbazole-9-yl)propionic acid, potassium bromide, sodium bromide, rubidium bromide and europium bromide; a lone pair-containing functional group common in molecules of the organic dopant and a functional group common in the Lewis base comprise, but are not limited to, a phosphate group, a phosphoryl chloride group, a phosphoryl group, an organic phosphate group, a sulfonic acid group, a thioketone group, an amino group, a hydroxyl group, a cyano group, an aldehyde group, a carboxyl group, a ketone group and a nitrile group; and an unoccupied electron orbit-containing functional group common in molecules of the organic dopant and a functional group common in the Lewis acid comprise, but are not limited to, a carbon-carbon double bond group, a carbon-carbon triple bond group and a boric acid; and an ion common in molecules of the inorganic dopant comprises, but is not limited to, one or a mixture in any proportion of a sodium ion, a potassium ion, a rubidium ion, a europium ion, a strontium ion, a silver ion, an indium ion and a bismuth ion.

7. The doped perovskite semiconductors capable of realizing p-type, n-type and i-type electrical conductivities according to claim 1, wherein two or more types of doped perovskite semiconductors capable of realizing p-type, n-type and i-type electrical conductivities form a homogeneous junction (homojunction) or heterogeneous junction (heterojunction); two or more perovskite semiconductor materials forming the aforementioned homojunction have similar overall compositions and the same band gap;
two or more perovskite semiconductor materials forming the aforementioned heterojunction have significantly different overall compositions and generally different band gaps, and are also possible to have the same band gap under special circumstances;
and the aforementioned homojunctions and heterojunctions are used for constructing electronic or optoelectronic devices, which can be, but are not limited to, diodes, transistors, solar cells, detectors, scintillators, light-emitting diodes or semiconductor lasers.

8. The doped perovskite semiconductors capable of realizing p-type, n-type and i-type electrical conductivities according to claim 1, wherein the carrier concentration reaches above 10²⁰ cm⁻³; the carrier mobility reaches above 1000 cm² V⁻¹s⁻¹; and a photoluminescence quantum yield reaches above 95%.

9. The doped perovskite semiconductors capable of realizing p-type, n-type and i-type electrical conductivities according to claim 1, wherein when the hole concentration in a p-type perovskite semiconductor reaches above 10¹⁸ cm⁻³, the p-type perovskite semiconductor is also called a “heavily doped p-type perovskite semiconductor” or a “p⁺-type perovskite semiconductor”; and when the electron concentration in an n-type perovskite semiconductor reaches above 10¹⁸ cm⁻³, the n-type perovskite semiconductor is also called a “heavily doped n-type perovskite semiconductor” or an “n⁺-type perovskite semiconductor”.

10. The doped perovskite semiconductor capable of realizing p-type, n-type and i-type electrical conductivities according to claim 7, wherein the electronic or optoelectronic devices are prepared by homojunctions or heterojunctions consisting of doped perovskite materials, together with a substrate, an anode, an electron-transport material, a hole-transport material, a cathode, and a combination of any these functional materials; and the doped perovskite semiconductors can be used without having to employ electron-transport layers or hole-transport layers to form perovskite electronic or optoelectronic devices without charge-transport layers.
